(19) United States
(12) Patent Application Publication
(10) Pub. No.: US 2010/0000684 A1
(43) Pub. Date: Jan. 7, 2010

(54) Dry etching apparatus

(76) Inventor: Jong Yong Choi, Yongin-si (KR)

Correspondence Address: OBER KALER;Ober, Kaler, Grimes & Shriver, 120 East Baltimore Street, Baltimore, MD, 21202-1643, US

(21) Appl. No.: 12/459,586

(22) Filed: Jul. 2, 2009

(30) Foreign Application Priority Data
Jul. 3, 2008 (KR) 10-2008-0064236
Jun. 4, 2009 (KR) 10-2009-0049502

(51) Int. Cl. H01L 21/465

(52) U.S. Cl. 156/345.43; 257/E21.485

(57) ABSTRACT

A dry etching apparatus is disclosed, which is capable of forming a uniform pattern in a substrate surface, the dry etching apparatus for etching at least one substrate through the use of plasma, comprising the at least one substrate placed on a tray inside a chamber; a susceptor, provided inside the chamber while confronting with the at least one substrate, for supplying a high-frequency power to form the plasma; a grounding part provided beneath the susceptor while being untouchable to the susceptor; and an insulating part provided between the susceptor and the grounding part.

### CROSS REFERENCE TO RELATED APPLICATIONS

This application claims the benefit of the Korean Patent Application Nos. P2008-0064236 filed on Jul. 3, 2008, and P2009-0049502 filed on Jun. 4, 2009, which are hereby incorporated by reference as if fully set forth herein.

### BACKGROUND OF THE INVENTION

1. Field of the Invention

The present invention relates to a dry etching apparatus, and more particularly, to a dry etching apparatus which is capable of forming a uniform pattern in a substrate surface.

2. Discussion of the Related Art

A solar cell with a property of semiconductor converts a light energy into an electric energy.

A structure and principle of the solar cell according to the related art will be briefly explained as follows. The solar cell is formed in a PN-junction structure where a positive (P)-type semiconductor makes a junction with a negative (N)-type semiconductor. When a solar ray is incident on the solar cell with the PN-junction structure, holes (+) and electrons (−) are generated in the semiconductor owing to the energy of the solar ray. By an electric field generated in a PN-junction area, the holes (+) are drifted toward the P-type semiconductor and the electrons (−) are drifted toward the N-type semiconductor, whereby an electric power is produced with an occurrence of electric potential.

The solar cell can be largely classified into a wafer type solar cell and a thin film type solar cell.

The wafer type solar cell uses a wafer made of a semiconductor material such as silicon. Conversely, the thin film type solar cell is manufactured by forming a semiconductor in type of a thin film on a glass substrate.

The wafer type solar cell is disadvantageous in that the wafer type solar cell is thicker as compared to the thin film type solar cell and is manufactured with a higher-priced material. On the other hand, the wafer type solar cell is more efficient than the thin film type solar cell.

In order to maximize absorption of solar ray in the wafer type solar cell, an uneven structure (or concavo-convex pattern) is formed in a substrate surface of the wafer type solar cell.

If using a monocrystalline silicon substrate, a wet etching process such as an alkali etching is performed so as to form the uneven structure (or pattern) in a surface of the monocrystalline silicon substrate. Meanwhile, if using a polycrystalline silicon substrate, crystal molecules are arranged at different orientation directions so that it is difficult to form the uneven structure (or pattern) in a surface of the polycrystalline silicon substrate by the alkali etching.

Furthermore, if forming the uneven structure (or pattern) by the wet etching, the substrate is decreased in its thickness. In this respect, it is necessary to use a thicker substrate when performing the wet etching. Using the thicker substrate causes the increase in production cost of the solar cell.

Accordingly, there is a need for a new method for uniformly forming the uneven structure in the surface of the substrate without regard to the orientation direction of crystal molecules.

### SUMMARY OF THE INVENTION

Accordingly, the present invention is directed to a dry etching apparatus that substantially obviates one or more problems due to limitations and disadvantages of the related art.

An aspect of the present invention is to provide a dry etching apparatus, which is capable of forming a uniform pattern in a substrate surface.

Additional features and aspects of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these and other advantages and in accordance with the purpose of the invention, as embodied and broadly described herein, a dry etching apparatus, for etching at least one substrate through the use of plasma, comprises the at least one substrate placed on a tray inside a chamber; a susceptor, provided inside the chamber while confronting with the at least one substrate, for supplying a high-frequency power to form the plasma; a grounding part provided beneath the susceptor while being untouchable (not in contact with) the susceptor; and an insulating part provided between the susceptor and the grounding part.

The grounding part is formed in a rectangular or circular shaped flat panel with a central hole therein.

Also, the grounding part includes a mesh portion.

The grounding part includes a plurality of openings arranged in a grid configuration.

The grounding part is formed in shape of a rectangular or circular frame.

The insulating part is formed of a ceramic or Teflon material.

The insulating part comprises a first insulator confronting with a central portion of the susceptor; and a plurality of second insulators engaged with the first insulator, wherein the second insulator is bent to be confronting with a lateral surface of the susceptor and the rest of the susceptor except the central portion of the susceptor.

Each step-shaped surface is formed at a portion for engaging the first insulator and the second insulator with each other, and a portion for engaging the neighboring second insulators with each other, and wherein the first and second insulators are engaged through the step-shaped surface.

Furthermore, the dry etching apparatus additionally comprises a first sealing member provided between the insulating part and the susceptor; and a second sealing member provided between the insulating part and the grounding part.

Also, the dry etching apparatus comprises a susceptor supporting member for electrically connecting the susceptor to a rear surface of the substrate by elevating the grounding part; and an electrode rod for supplying the high-frequency power to the susceptor, the electrode rod passing through the susceptor supporting member.

The susceptor supporting member comprises a first supporter connected with the susceptor by passing through the chamber, the grounding part, and the insulating part; a second supporter connected with the grounding part by passing through the chamber; and a plate connected with the first and second supporters.

Also, the tray for supporting the at least one substrate is electrically connected with the susceptor by elevation of the susceptor.

In addition, the dry etching apparatus comprises a bellows provided between the chamber and the plate.

The dry etching apparatus further comprises a bellows provided between a bottom surface of the chamber and the grounding part.

The grounding part is grounded by the bellows.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 illustrates a dry etching apparatus according to one embodiment of the present invention;

FIG. 2 illustrates a perspective view of explaining an insulating part in the dry etching apparatus according to one embodiment of the present invention;

FIG. 3 illustrates a perspective view of explaining a grounding part according to the first embodiment of the present invention;

FIG. 4 illustrates a perspective view of explaining another grounding part according to the first embodiment of the present invention;

FIG. 5 illustrates a dry etching apparatus according to another embodiment of the present invention;

FIG. 6 illustrates a perspective view of explaining a grounding part according to the second embodiment of the present invention;

FIG. 7 illustrates a perspective view of explaining a grounding part according to the third embodiment of the present invention;

FIG. 8 illustrates a perspective view of explaining a grounding part according to the fourth embodiment of the present invention; and

FIGS. 9(A and B) illustrates an operation of dry etching apparatus according to the present invention.

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

Hereinafter, a dry etching apparatus according to the present invention and its operation method will be described with reference to the accompanying drawings.

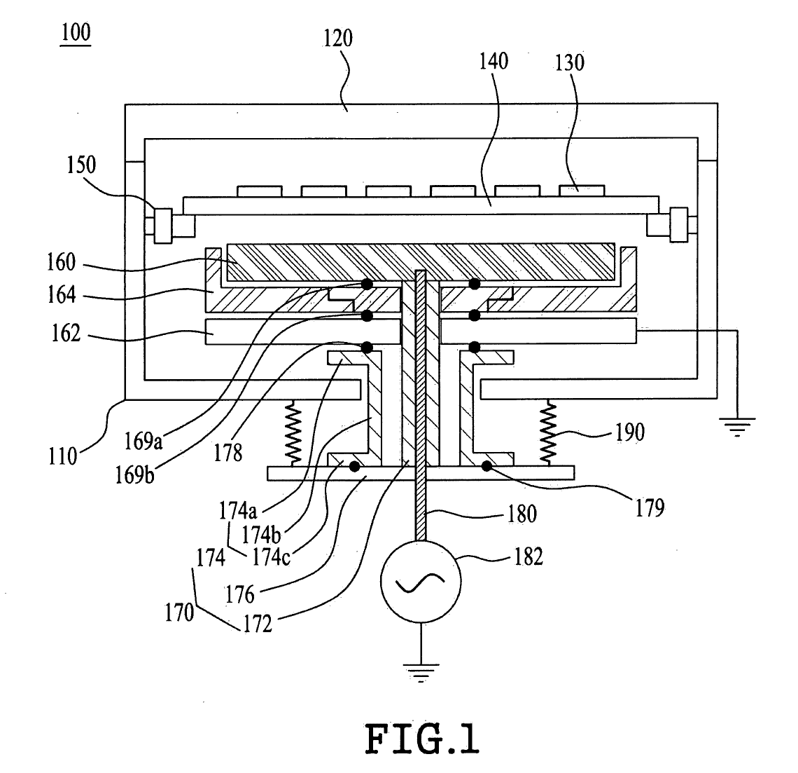

FIG. 1 illustrates a dry etching apparatus according to one embodiment of the present invention.

Referring to FIG. 1, the dry etching apparatus 100 according to one embodiment of the present invention includes a chamber 110; at least one substrate 130 placed inside the chamber 110; a susceptor 160 for forming a plasma to etch a surface of the substrate 130; a grounding part 162 for preventing an abnormal discharge from occurring beneath the susceptor 160, the grounding part 162 provided beneath the susceptor 160; an insulating part 164 for insulating the susceptor 160 and the grounding part 162 from each other, the insulating part 164 provided there between; and an electrode rod 180 for supplying a high-frequency power for the plasma to the susceptor 160, the electrode rod 180 being electrically connected with the susceptor 160 by passing through the grounding part 162 and the insulating part 164.

The chamber 110 provides a reaction space for a dry etching process (for example, a reactive ion etching process). In front of the chamber 110, there is a showerhead 120 installed so as to supply a processing gas used for formation of the plasma to the reaction space. For uniformly supplying the processing gas to the inside of the chamber 110, the showerhead 120 may be provided with a plurality of diffusion members. For example, the showerhead 120 may include a first diffusion member (not shown) for firstly diffusing the processing gas supplied from the external of the reaction space; and a second diffusion member (not shown) including a plurality of shower holes to secondly diffuse the processing gas, firstly diffused by the first diffusion member, into the inside of the reaction space. At this time, at least one of the first and second diffusion members may be rotated. The processing gas may be Cl₂, SF₆, NF₃, HBr, or their mixture. If needed, Ar, O₂, N₂, He, or their mixture may be added thereto.

The at least one substrate 130 may be positioned in the reaction space between the showerhead 120 and the susceptor 160 in such a way that the at least one substrate 130 confronts the susceptor 160. In this case, the at least one substrate 130 may be any one of a substrate or wafer used for manufacturing a solar cell, a substrate or wafer used for manufacturing a semiconductor device, or a substrate or glass substrate used for manufacturing a flat panel display device.

The at least one substrate 130 may be positioned inside the chamber 110 while being placed on a tray 140. The tray 140 may be formed in a rectangular shape or a circle shape, and the tray 140 may be formed of a metal material, for example, aluminum. That is, if the at least one substrate 130 placed on the tray 140 corresponds to the substrate or wafer used for manufacturing the solar cell, or the substrate or wafer used for manufacturing the flat panel display device, the tray 140 may be formed in the rectangular shape. If the at least one substrate 130 placed on the tray 140 corresponds to the substrate or wafer used for manufacturing the semiconductor device, the tray 140 may be formed in the circle shape.

In the meantime, if placing the plurality of substrates 130 on the tray 140, the plurality of substrates 130 may be arranged at fixed intervals in a matrix configuration, but it is not limited to this configuration.

The dry etching apparatus 100 according to one embodiment of the present invention may further include one or more tray supporting members 150 for supporting the tray 140.

Here, two tray supporting members 150 are respectively provided at both sidewalls of the chamber 110, the tray supporting members 150 being arranged in parallel. The tray supporting members 150 support the tray 140 transferred to the reaction space through an open chamber gate (not shown) by a tray transferring apparatus. The tray supporting member(s) 150 include a roller member, and the tray transferring apparatus may be a transferring robot or a conveyor.

The susceptor 160 is positioned inside the chamber 110 in such a way that the susceptor 160 faces a rear surface of the tray 140. The susceptor 160 generates the plasma through the use of high-frequency power supplied through the electrode rod 180, to thereby etch the surface of the substrate 130 placed on the tray 140. The susceptor 160 is identical in shape to the tray 140.

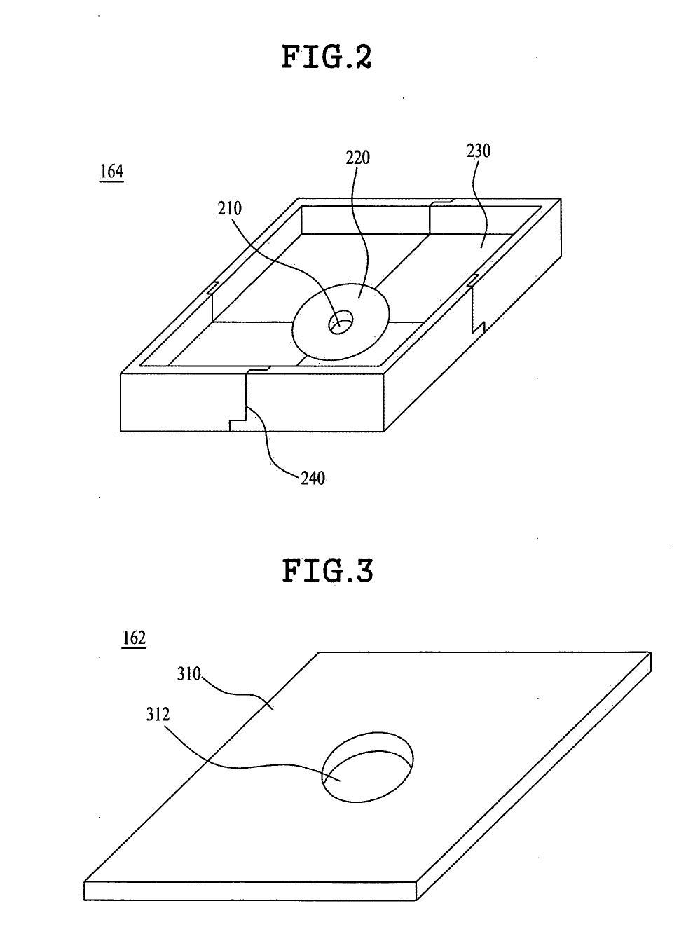

The insulating part 164 is positioned between the susceptor 160 and the grounding part 162, so as to electrically insulate the rear and lateral surfaces of the susceptor 160 from the grounding part 162. For this, as shown in FIG. 2, the insulating part 164 may include a first insulator 220 with a through hole 210; and a plurality of second insulators 230 to be engaged with the first insulator 220.

The first insulator 220 is positioned in such a way that the first insulator 220 confronts a central portion of the susceptor 160.

Each of the plurality of second insulators 230 is provided with a horizontal portion confronting the rest of the susceptor 160 except the central portion of the susceptor 160; and a vertical portion confronting with the lateral surface of the susceptor 160.

The horizontal portion in each second insulator 230 is engaged with the neighboring second insulators 230 as well as the first insulator 220. In this case, at least one step-shaped surface 240 is formed at a portion for engaging the first insulator 220 and the second insulator 230 with each other, and a portion for engaging the neighboring second insulators 230 with each other. This step-shaped surface 240 enables the increase of grounding path between the susceptor 160 and the grounding part 162, and also enables ease of engagement.

The insulating part 164 may be formed of a ceramic material or Teflon™ material which is capable of enhancing a density of the plasma generated in the reaction space, and is also capable of preventing the abnormal discharge. Preferably, the insulating part 164 is formed of Teflon™ material, but not necessarily. A dielectric constant of Teflon™ material is higher than that of ceramic material. Owing to the high dielectric constant of Teflon™ material, even though the insulating part 164 is formed at a small thickness (for example, 40 mmor less), a high insulating efficiency can be realized. Also, since Teflon™ material is not reactive on an etching gas, it is possible to minimize a sag in the susceptor 160.

The grounding part 162, formed in the same shape as that of the susceptor 160, is electrically grounded by a ground (not shown). In case of a general dry etching apparatus, it is impossible to make a direct grounding in the susceptor 160, whereby the abnormal discharge is generated beneath the susceptor 160. Meanwhile, in case of the dry etching apparatus according to the present invention, the grounding part 162 is grounded while being positioned beneath the susceptor 160 so that it is possible to prevent the abnormal discharge from occurring beneath the susceptor 160.

As shown in FIG. 3, the grounding part 162 according to the first embodiment of the present invention may be a rectangular-shaped flat panel 310 with a central hole 312, but it is not limited to this structure. The grounding part 162 may be a circular-shaped flat panel based on the shape of the susceptor 160.

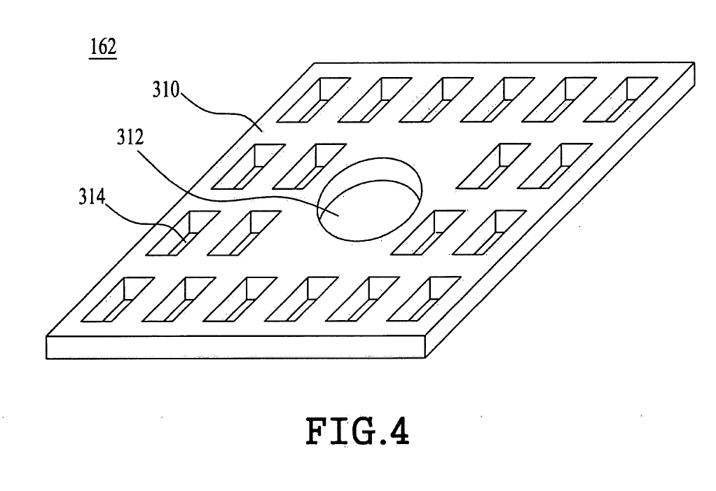

As shown in FIG. 4, the grounding part 162 according to the first embodiment of the present invention may further include a plurality of openings 314 arranged in a grid configuration. In this case, each opening 314 may be formed in a rectangular shape or a circular shape.

Referring back to FIG. 1, a first sealing member 169a is provided between the susceptor 160 and the insulating part 164, and a second sealing member 169b is provided between the grounding part 162 and the insulating part 164. In this case, the first and second sealing members 169a and 169b may be respectively O-rings, and the first sealing member 169a may be positioned above the first insulator 220. The first and second sealing members 169a and 169b separate the reaction space inside the chamber 110 from an external atmospheric space.

The susceptor 160, the grounding part 162, and the insulating part 164 may be integrated into one body with the first and second sealing members 169a and 169b positioned in-between by a connection member (not shown).

The dry etching apparatus 100 according to one embodiment of the present invention may further include a susceptor supporting member 170 and a high-frequency power supplier 182.

The susceptor supporting member 170 includes a first supporter 172, a second supporter 174, and a plate 176.

One end of the first supporter 172 is connected with the central portion of the susceptor 160 by sequentially passing through the bottom surface of the chamber 110, the central hole 312 of the grounding part 162, and the through hole 210 of the insulating part 164; and the other end of the first supporter 172 supports the rear surface of the susceptor 160 while being connected with the plate 176.

The second supporter 174 supports the rear surface of the grounding part 162 by passing through the bottom surface of the chamber 110. For this, the second supporter 174 may include an upper supporter 174a which is connected to the grounding part 162 with a third sealing member 178 interposed in-between; a lateral supporter 174b which is perpendicularly bent from the upper supporter 174a being adjacent to the first supporter 172; and a lower supporter 174c which is bent from the lateral supporter 174b while being parallel to the upper supporter 174a, and is connected to the plate 176 with a fourth sealing member 179 interposed in-between. At this time, the lateral supporter 174b may be provided with a through hole through which the first supporter 172 passes. The third and fourth sealing members 178 and 179 may be respectively O-rings.

The plate 176 supports the other end of the first supporter 172 and the lower supporter 174c of the second supporter 174.

The aforementioned susceptor supporting member 170 can support the susceptor 160, and also elevate or lower the susceptor 160 by an elevating apparatus (not shown). At this time, the elevating apparatus elevates the susceptor supporting member 170 to a predetermined height which is suitable for loading or unloading the tray 140 when the tray 140 is loaded on or unloaded from the tray supporting member 150. After completing the loading or unloading of the tray 140, the elevating apparatus elevates the susceptor supporting member 170 so that the susceptor 160 is electrically connected with the tray 140, to thereby carry out an etching process.

The high-frequency power supplier 182 supplies high-frequency power to the electrode rod 180 which is electrically connected with the susceptor 160 by passing through the susceptor supporting member 170. This high-frequency power supplier 182 supplies the high-frequency power to the electrode rod 180 so as to apply the high-frequency power to the tray 140 when the susceptor 160 is electrically connected with the tray 140 by the susceptor supporting member 170.

The electrode rod 180 is electrically connected with the central portion of the susceptor 160 by passing through the plate 176 and the first supporter 172 in the susceptor supporting member 170.

The dry etching apparatus 100 according to one embodiment of the present invention may further include a bellows 190 for protecting the high-frequency power supplier 182 and the susceptor supporting member 170 being exposed to the external of the chamber 110.

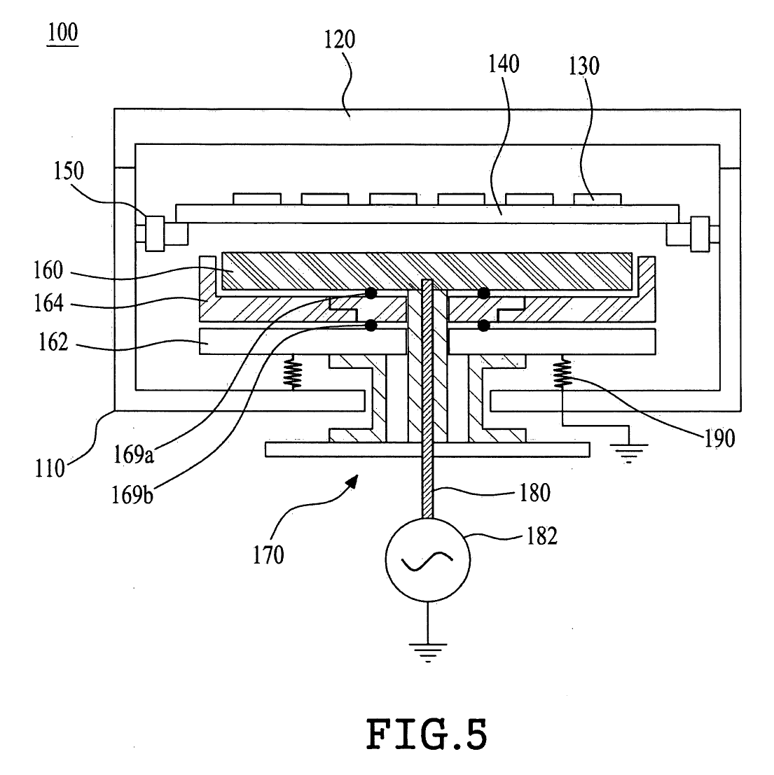

The bellows 190 is provided between the lower surface of the chamber 110 and the plate 176 of the susceptor supporting member 170. This bellows 190 is formed of a flexible material, which is capable of protecting the high-frequency power supplier 182 and the susceptor supporting member 170 being exposed to the external of the chamber 110 by its contraction and expansion. As shown in FIG. 5, the bellows 190 may be provided between the internal bottom surface of the chamber 110 and the grounding part 162 of the susceptor 160. In this case, the third and fourth sealing members 178 and 179 shown in FIG. 1 may be omitted. Thus, the bellows 190 provided inside the chamber 110 enables the decrease in size of the dry etching apparatus 100.

In FIG. 5, the grounding part 162 may be grounded to the external ground by the bellows 190.

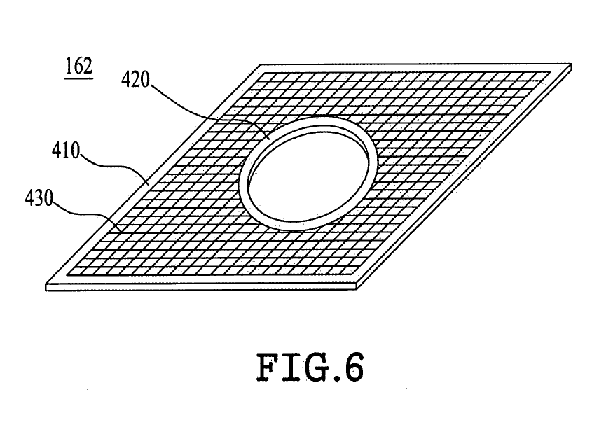

FIG. 6 illustrates a perspective view for explaining a grounding part according to a second embodiment of the present invention.

Referring to FIG. 6, the grounding part 162 according to the second embodiment of the present invention may be provided with an external frame 410, a central frame 420, and a mesh portion 430.

The external frame 410 is formed in a rectangular shape corresponding to the edge of the susceptor 160. FIG. 6 illustrates the rectangular-shaped external frame 410, but the shape of the external frame 410 is not limited to the rectangular shape. If the susceptor 160 is formed in a circular shape, the external frame 410 may be formed in the circular shape.

The central frame 420 is formed in the external frame 410 such that the first supporter 172 passes through the central frame 420. Then, second and third sealing members 169b and 178 may be respectively provided on upper and lower surfaces of the central frame 420 so as to separate the reaction space inside the chamber 110 from the external atmospheric space.

The mesh portion 430 is formed in a mesh type to connect the external frame 410 and the central frame 420 with each other.

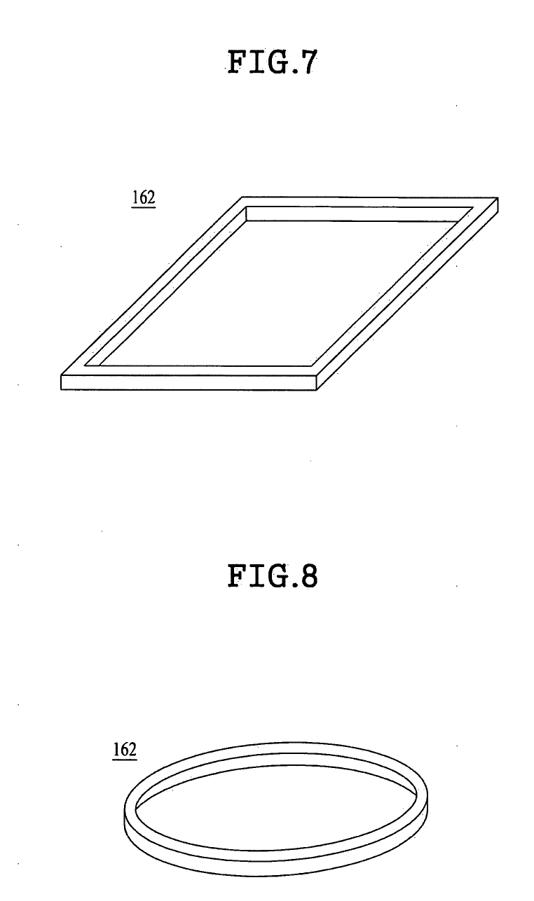

FIG. 7 illustrates a perspective view for explaining a grounding part according to a third embodiment of the present invention.

Referring to FIG. 7, the grounding part 162 according to the third embodiment of the present invention may be formed in a rectangular-shaped frame to be overlapped with the edge of the susceptor 160. Then, second and third sealing members 169b and 178 may be respectively provided on upper and lower surfaces of the grounding part 162 formed in shape of the rectangular frame so as to separate the reaction space inside the chamber 110 from the external atmospheric space.

FIG. 8 illustrates a perspective view for explaining a grounding part according to a fourth embodiment of the present invention.

Referring to FIG. 8, the grounding part 162 according to the fourth embodiment of the present invention may be formed in a circular-shaped frame to be overlapped with the edge of the susceptor 160. Then, second and third sealing members 169b and 178 may be respectively provided on upper and lower surfaces of the grounding part 162 formed in shape of the circular frame so as to separate the reaction space inside the chamber 110 from the external atmospheric space.

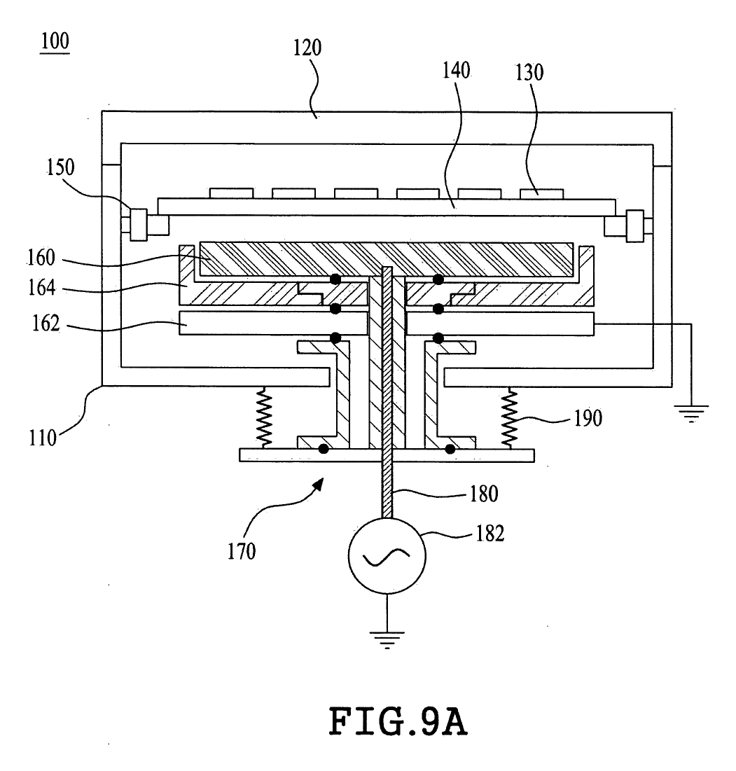

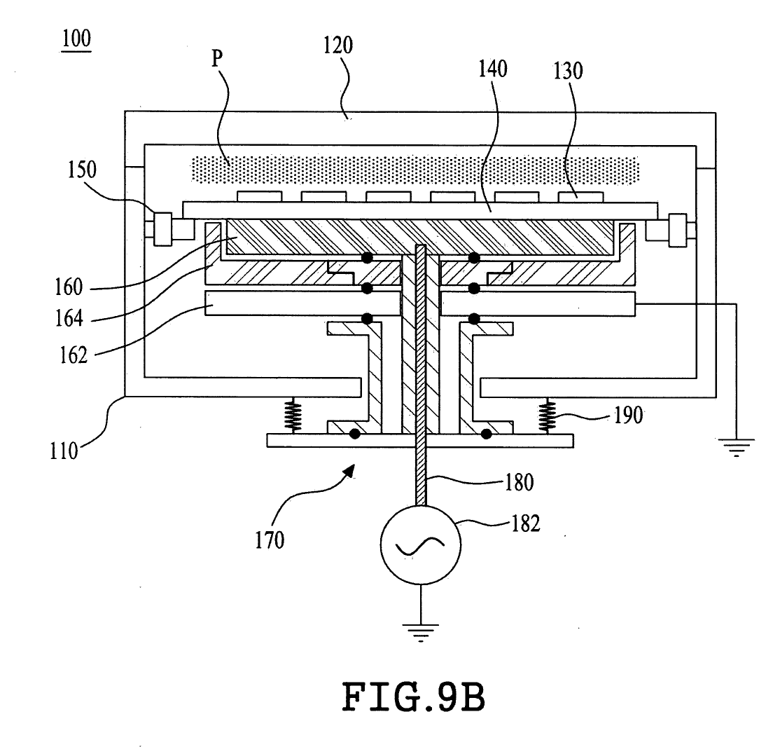

An operation of the dry etching apparatus according to the present invention will be explained with reference to FIGS. 9(A and B).

As shown in FIG. 9(A), the external tray 140 is loaded on the tray supporting member 150. According as the elevating apparatus is driven, the susceptor supporting member 170 is lowered so that the susceptor 160 is maintained at a predetermined height.

When the tray 140 is supported by the tray supporting member 150, as shown in FIG. 9(B), the susceptor 160 is elevated by elevation of the susceptor supporting member 170 according to an operation of the elevating apparatus, whereby the susceptor 160 is electrically connected with the rear surface of the tray 140.

As the high-frequency power supplied from the high-frequency power supplier 182 to the electrode rod 180 is applied to the tray 140 through the susceptor 160, and simultaneously the processing gas is supplied to the reaction space from the showerhead 120, plasma (P) is generated in the reaction space of the chamber 110, that is, between the showerhead 120 and the tray 140. Then, ion and radical are generated by collision between the processing gas and electrons accelerated by the plasma (P), and the generated ion and radical enter into the substrate 130 placed on the tray 140, whereby the etching process is carried out.

After completing the etching process, the susceptor 160 is lowered, and the tray 140 supported by the tray supporting member 150 is unloaded.

In the dry etching apparatus 100 according to the present invention, the grounding part 162 is provided beneath the susceptor 160 so as to prevent the discharge from occurring beneath the susceptor 160, so that it is possible to realize the wide processing margin and uniform etching through enhancement of plasma density.

In the meantime, the dry etching apparatus 100 according to the present invention may be used for forming an uneven structure (or concavo-convex pattern) in a surface of a substrate so as to maximize absorption of solar ray when manufacturing a wafer type solar cell. Through a dry etching process performed by the dry etching apparatus 100 according to the present invention, the uneven structure can be uniformly formed in the surface of the substrate for the wafer type solar cell without regard to orientation direction of crystal molecules. Accordingly, the dry etching apparatus 100 according to the present invention enables the use of relatively-thin substrate on the process of manufacturing the wafer type solar cell.

Furthermore, the dry etching apparatus 100 according to the present invention can be used for a dry etching process when manufacturing a semiconductor device or a flat panel display device.

As mentioned above, the dry etching apparatus 100 according to the present invention includes the grounding part 162 provided beneath the susceptor 160, whereby it is possible to prevent the abnormal discharge from occurring beneath the susceptor 160, thereby realizing the wide processing margin and uniform etching through enhancement of plasma density.

Also, the uneven structure can be uniformly formed in the surface of the substrate for the wafer type solar cell without regard to orientation direction of crystal molecules, through the dry etching process performed by the dry etching apparatus 100 according to the present invention.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A dry etching apparatus, for etching at least one substrate through the use of plasma, comprising:
a chamber defining a space, a tray inside said chamber, and at least one substrate seated on said tray inside said chamber;
a susceptor, provided inside the chamber facing the at least one substrate, for supplying a high-frequency power to form said plasma;
a grounding part provided beneath the susceptor and untouchable with the susceptor; and
an insulating part provided between the susceptor and the grounding part.

2. The dry etching apparatus of claim 1, wherein the grounding part is formed in a rectangular or circular shaped flat panel with a central hole therein.

3. The dry etching apparatus of claim 1, wherein the grounding part includes a mesh portion.

4. The dry etching apparatus of claim 1, wherein the grounding part includes a plurality of openings arranged in a grid configuration.

5. The dry etching apparatus of claim 1, wherein the grounding part is formed in shape of a rectangular or circular frame.

6. The dry etching apparatus of claim 1, wherein the insulating part is formed of a ceramic or Teflon material.

7. The dry etching apparatus of claim 1, wherein the insulating part comprises:
a first insulator confronting with a central portion of the susceptor; and
a plurality of second insulators engaged with the first insulator, wherein the second insulator is bent to be confronting with a lateral surface of the susceptor and the rest of the susceptor except the central portion of the susceptor.

8. The dry etching apparatus of claim 7, wherein each step-shaped surface is formed at a portion for engaging the first insulator and the second insulator with each other, and a portion for engaging the neighboring second insulators with each other, and
wherein the first and second insulators are engaged through the step-shaped surface.

9. The dry etching apparatus of claim 7, further comprising:
a first sealing member provided between the insulating part and the susceptor; and
a second sealing member provided between the insulating part and the grounding part.

10. The dry etching apparatus of claim 1, further comprising:
a susceptor supporting member for electrically connecting the susceptor to a rear surface of the substrate by elevating the grounding part; and
an electrode rod for supplying the high-frequency power to the susceptor, the electrode rod passing through the susceptor supporting member.

11. The dry etching apparatus of claim 10, wherein the susceptor supporting member comprises:
a first supporter connected with the susceptor by passing through the chamber, the grounding part, and the insulating part;
a second supporter connected with the grounding part by passing through the chamber; and
a plate connected with the first and second supporters.

12. The dry etching apparatus of claim 10, wherein the tray for supporting the at least one substrate is electrically connected with the susceptor by elevation of the susceptor.

13. The dry etching apparatus of claim 11, further comprising:
a bellows provided between the chamber and the plate.

14. The dry etching apparatus of claim 1, further comprising:
a bellows provided between a bottom surface of the chamber and the grounding part.

15. The dry etching apparatus of claim 14, wherein the grounding part is grounded by the bellows.
